(19) United States
(12) Patent Application Publication
(10) Pub. No.: US 2006/0097808 A1
(43) Pub. Date: May 11, 2006

(54) Semiconductor device and semiconductor chip

(75) Inventor: Kazuya Kawamura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/266,212

(22) Filed: Nov. 4, 2005

(30) Foreign Application Priority Data
Nov. 5, 2004 (JP) 2004-321835

(51) Int. Cl. H03B 5/32

(52) U.S. Cl. 331/158

(57) ABSTRACT

A semiconductor device according to an embodiment of the present invention includes a semiconductor chip and a quartz oscillator. The semiconductor chip includes a first clock signal input terminal receiving a clock signal from the quartz oscillator, and a second clock signal input terminal receiving an externally generated clock signal. According to the device, it is possible to prevent simultaneous input of the clock signal from the quartz oscillator and the externally generated clock signal to the semiconductor chip.

### BACKGROUND OF THE INVENTION

1. Field of the Invention

The present invention relates to a semiconductor device and a semiconductor chip. In particular, the invention relates to a semiconductor device equipped with a piezoelectric oscillator and a semiconductor chip connected with the piezoelectric oscillator.

2. Description of Related Art

Up to now, piezoelectric oscillators such as a quartz oscillator or ceramic oscillator have been widely used as a clock generator for a computer device. Besides, available frequencies of the piezoelectric oscillators range from, for example, 50 MHz to 125 MHz.

Meanwhile, there have been reported some schemes to apply the same frequency as the piezoelectric oscillator mounted to an electronic device such as a pachinko machine to induce an erroneous operation of the electronic device for the purpose of illegally reading important control information.

As a countermeasure against such an illegal obtainment of the control information, the piezoelectric oscillator mounted to the electronic device has been designed not to allow someone to readily know its frequency. For example, it is known that the piezoelectric oscillator is incorporated into a semiconductor device together with a semiconductor chip as disclosed in Japanese Unexamined Patent Publication No. 7-122937.

However, assuming that such a semiconductor device receives a predetermined clock signal for a pre-shipment operation test after being manufactured, for example, the semiconductor chip inside the semiconductor device receives an externally applied clock signal as well as the clock signal from the piezoelectric oscillator. This means that the semiconductor chip in the semiconductor device receives the two kinds of clock signals at a time, leading to an erroneous operation to hinder an accurate operation test.

As another related art, Japanese Unexamined Patent Publication No. 10-307167 discloses a testing device for an integrated circuit, which includes two clock signal input terminals CLK1 and CLK2 connected with a flip-flop (F/F) circuit, and is capable of switching CLK1 and CLK2 from each other to be connected with the F/F by means of a selector circuit 1 depending on whether the device enters a test mode or a normal mode.

As mentioned above, there arises a problem that, upon the operation test of the semiconductor device, the semiconductor chip provided inside the semiconductor device receives a clock signal output from the piezoelectric oscillator and an externally applied clock signal at a time, resulting in an erroneous operation of the semiconductor chip.

### SUMMARY OF THE INVENTION

According to an aspect of the present invention, a semiconductor device includes a semiconductor chip and a piezoelectric oscillator. The semiconductor chip includes a first clock signal input terminal receiving a clock signal output from the piezoelectric oscillator and a second clock signal input terminal receiving an externally generated clock signal.

The first clock signal input terminal receiving the clock signal from the piezoelectric oscillator and the second clock signal input terminal receiving the externally generated clock signal are separately provided this way, whereby it is possible to prevent the simultaneous input of the clock signal from the piezoelectric oscillator and the externally generated clock signal to the semiconductor chip.

### BRIEF DESCRIPTION OF THE DRAWINGS

The above and other objects, advantages and features of the present invention will be more apparent from the following description taken in conjunction with the accompanying drawings, in which:

FIG. 1 is a top view showing the structure of a semiconductor device according to an embodiment of the present invention;

FIG. 2 shows how to connect input terminals for clock signals with an internal circuit in the semiconductor device according to the embodiment of the present invention;

FIG. 3 is a top view showing the structure of the semiconductor device according to the embodiment of the present invention, from which a quartz oscillator is removed;

FIG. 4 shows how to connect input terminals for clock signals with an internal circuit in the semiconductor device according to the embodiment of the present invention, from which the quartz oscillator is removed;

FIG. 5 shows how to connect the input terminals for clock signals with the internal circuit in the semiconductor device as another example of the embodiment of the present invention; and

FIG. 6 is a perspective view showing the structure of a semiconductor device according to another embodiment of the present invention.

### DESCRIPTION OF THE PREFERRED EMBODIMENTS

The invention will be now described herein with reference to illustrative embodiments.

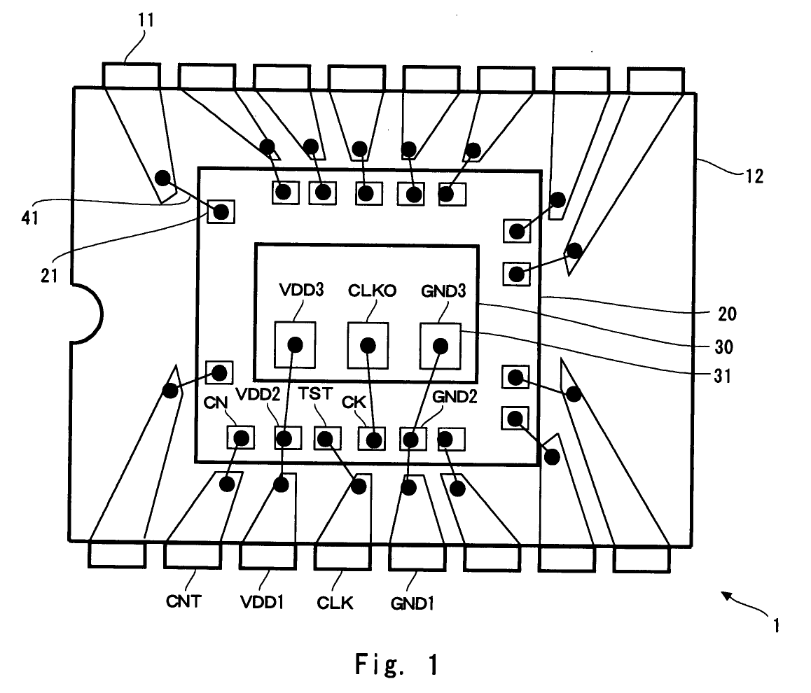

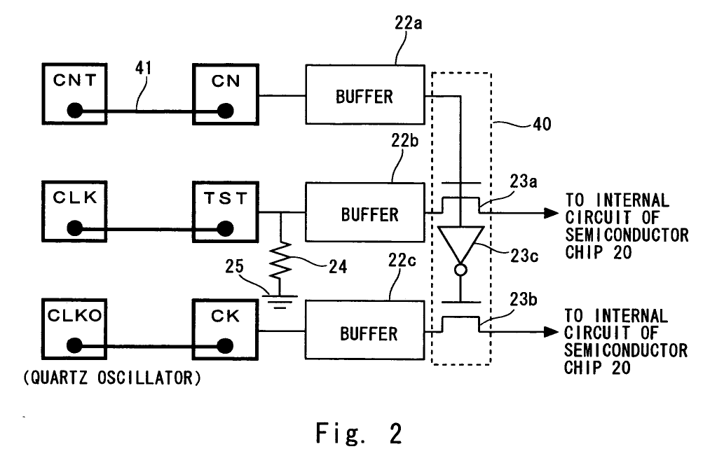

Hereinbelow, a description is given of the structure of a semiconductor device according to a first embodiment of the present invention with reference to the accompanying drawings. FIG. 1 is a top view showing the structure of the semiconductor device according to the first embodiment of the present invention. FIG. 2 shows how to connect input terminals for clock signals with an internal circuit in the semiconductor device according to the first embodiment of the present invention.

In FIG. 1, a semiconductor device 1 is structured such that leading edges of plural leads 11 protrude from a resin package 12. The plural leads 11 include a control signal lead CNT (hereinafter, referred to as “lead CNT”), a power supply lead VDD1 (hereinafter, referred to as “lead VDD1”), a clock signal lead CLK (hereinafter, referred to as “lead CLK”), and a ground lead GND1 (hereinafter, referred to as “lead GND1”).

In addition, as shown in FIG. 1, a semiconductor chip 20 is provided at the center of the resin package 12. Further, a quartz oscillator 30 as a piezoelectric oscillator is laminated on the semiconductor chip 20. The quartz oscillator 30 generates clock signals of a predetermined frequency.

Plural terminals 21 are provided around the perimeter of the upper surface of the semiconductor chip 20. The plural terminals 21 include a control signal terminal CN (hereinafter, referred to as “terminal CN”), a power supply terminal VDD2 (hereinafter, referred to as “terminal VDD2”), a test clock signal terminal TST (hereinafter, referred to as “terminal TST”), a clock signal terminal CK (hereinafter, referred to as “terminal CK”), and a ground signal terminal GND2 (hereinafter, referred to as “terminal GND2”).

Plural terminals 31 are provided on the upper surface of the quartz oscillator 30. More specifically, a power supply terminal VDD3 (hereinafter, referred to as “terminal VDD3”), a clock signal terminal CLK0 (hereinafter, referred to as “terminal CLK0”), and a ground terminal GND3 (hereinafter, referred to as “terminal GND3”) are provided.

Here, it is assumed that the quartz oscillator 30 is covered with an insulator except for the terminals (CLK0, GND3, and VDD3).

Further, as shown in FIG. 1, the leads 11, the terminals 21 on the semiconductor chip 20, and the terminals 31 on the quartz oscillator 30 are electrically connected through wire bonding by means of wires 41.

A detailed description is made of how the leads 11, and the terminals 21 and 31 are connected with reference to the drawings.

As shown in FIG. 1, the lead CNT is electrically connected with the terminal CN through wire bonding. The lead CNT receives a switching signal for switching a switch 40.

The lead VDD1 is electrically connected with the terminal VDD2 and the terminal VDD2 is electrically connected with the terminal VDD3 through wire bonding, and an external power supply supplies power to the semiconductor chip 20 and the quartz oscillator 30 by way of the lead VDD1, the terminal VDD2, and the terminal VDD3. The semiconductor chip 20 and the quartz oscillator 30 operate with the supplied power.

The lead CLK is electrically connected with the terminal TST through wire bonding, and externally generated clock signals are input to the semiconductor chip 20 by way of the lead CLK, and the terminal TST.

The lead GND1 is electrically connected with the terminal GND2, and the terminal GND2 is electrically connected with the terminal GND3 through wire bonding, and the terminal GND2 of the semiconductor chip 20 and the terminal GND3 of the quartz oscillator 30 are grounded.

The terminal CK is electrically connected with the terminal CLK0 through wire bonding, and clock signals output from the quartz oscillator 30 are input to the semiconductor chip 20 by way of the terminal CLK and the terminal CK.

Further, as shown in FIG. 2, the semiconductor device 1 includes the switch 40 selecting one of a clock signal input to the terminal TST and a clock signal input to the terminal CK. The switch 40 includes, as shown in FIG. 2, MOS transistors 23a and 23b, and an inverter 23c.

Buffers 22a to 22c are provided between the internal circuit of the semiconductor chip 20 and the terminal CN, between the internal circuit of the semiconductor chip 20 and the terminal TST, and between the internal circuit of the semiconductor chip 20 and the terminal CK, respectively, and adapted to output signals input to the buffers 22a to 22c to the internal circuit of the semiconductor chip 20.

As shown in FIG. 2, a resistor 24 is provided between the terminal TST and a ground potential 25. The resistor 24 functions to pull the potential down to the ground potential 25 if no signal is input to the terminal TST. Here, the resistor 24 has a large resistance value as compared with an output impedance of the externally applied clock signal.

Next, an operation of the semiconductor device according to this embodiment of the present invention is described with reference to the drawings.

In FIG. 2, during a normal operation, the switch 40 as a selector is set to select a clock signal input through the terminal CLK0 and the terminal CK, and not to select a clock signal input through the lead CLK and the terminal TST.

Therefore, during the normal operation, the clock signals output from the quartz oscillator 30 are output to the internal circuit of the semiconductor chip 20 by way of the terminal CLK0 and the terminal CK. At this time, the semiconductor chip 20 operates in response to a clock signal from the quartz oscillator 30.

Next, during a test operation, a switching signal for switching the switch 40 is input to the lead CNT of the semiconductor device 1 by use of a testing device. When the switching signal for switching the switch 40 is input to the lead CNT (For example, at HIGH level), the switch 40 selects the clock signals input through the lead CLK and the terminal TST, not the clock signals input through the terminal CLK0 and the terminal CK.

Being input to the lead CLK, the test clock signal is output to the internal circuit of the semiconductor chip 20 by way of the lead CLK and the terminal TST. Also, the resistor 24 serves to pull the potential remaining between the terminal TST and the buffer 22b down to the ground potential 25. As the test clock signal, a signal having the same frequency as the clock signal from the quartz oscillator 30 is used.

Thus, during the test operation, the clock signals generated outside the semiconductor device 1 are output to the semiconductor chip 20 by way of the lead CLK and the terminal TST. At this time, the semiconductor chip 20 operates in response to the externally generated clock signals.

In this way, the terminal CK receiving the clock signal from the quartz oscillator 30 and the terminal TST receiving the externally generated clock signals are separately provided, thereby making it possible to avoid the simultaneous input of the clock signal from the quartz oscillator 30 and the externally generated clock signal to the semiconductor chip 20. Further, the terminal TST receiving the externally generated clock signal is not connected with the quartz oscillator 30, so the externally generated clock signals are by no means input to the quartz oscillator 30. Hence, there is no fear that the quartz oscillator 30 causes an erroneous operation.

Further, since the switch 40 selecting a clock signal input to either the terminal TST or the terminal CK is provided, the semiconductor chip 20 can reliably operate in accordance with the clock signal output from the quartz oscillator 30 when the clock signal input to the terminal CK is selected, and reliably operated in accordance with the externally generated clock signal when the clock signal input to the terminal TST is selected.

Further, the resistor 24 is provided between the terminal TST and the ground 25. Hence, while the semiconductor chip 20 is operating in accordance with the clock signal output from the quartz oscillator 30, the residual potential between the terminal TST and the buffer 22b can be pulled down to the ground 25 to save the power consumption of the buffer 22b. Moreover, the resistor 24 has a large resistance value as compared with the output impedance of the externally generated clock signal. Thus, even while the semiconductor chip 20 is operating in accordance with the externally applied clock signal, the resistor 24 does not influence the waveform of the externally generated clock signal.

The semiconductor chip 20 may detect the externally generated clock signal input to the lead CLK and the terminal TST to select the clock signal input to the terminal TST. When it is detected that the externally generated clock signal is input to the lead CLK and the terminal TST, the switch 40 selects the clock signal input to the terminal TST, not the clock signal input to the terminal CK. In this case as well, the externally generated clock signal can be automatically output to the internal circuit of the semiconductor chip 20 without inputting a signal for switching the switch 40 from the lead CNT, in accordance with the input of the externally generated clock signal to the lead CLK and the terminal TST. Therefore, it is possible to more simply and accurately prevent the simultaneous input of the clock signal from the quartz oscillator 30 and the externally generated clock signal to the semiconductor chip 20.

Furthermore, the semiconductor chip 20 may detect predetermined number of pulsed of externally generated clock signal to select the clock signal input to the terminal TST. When it is detected that the externally generated clock signal is input to the lead CLK and the terminal TST by a given number of pulses, the switch 40 selects the clock signal input to the terminal TST, not the clock signal input to the terminal CK. Also in this case, similar beneficial effects are attained.

Even if the quartz oscillator 30 is removed from the thus-structured semiconductor device 1 according to the first embodiment, the resulting semiconductor device 1a can exert the same function.

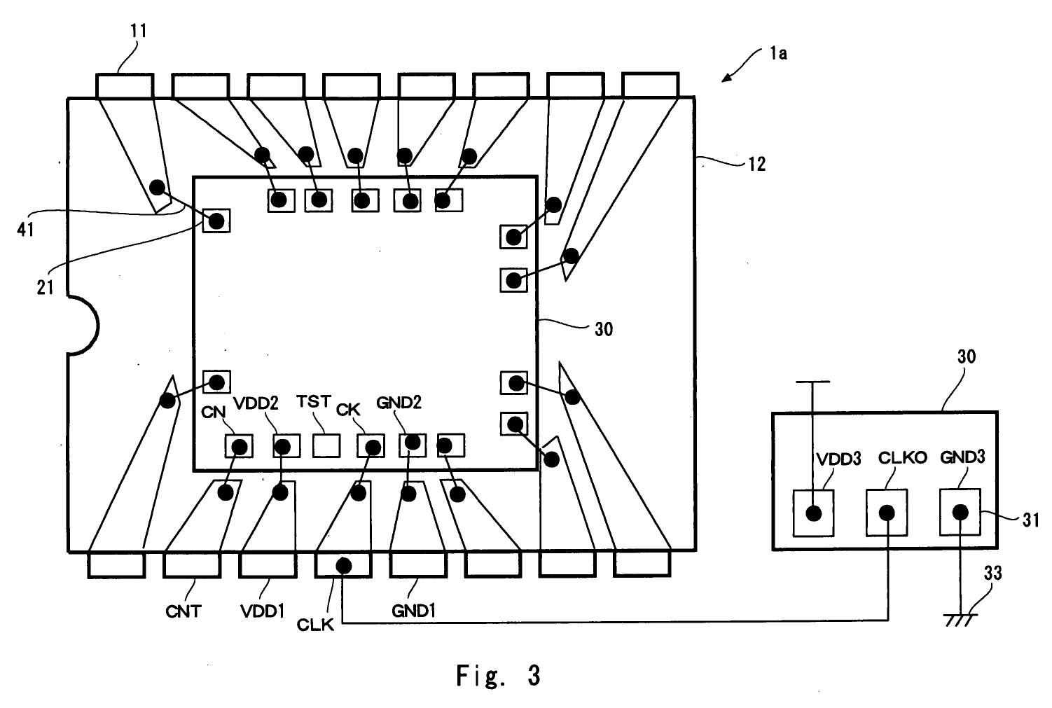

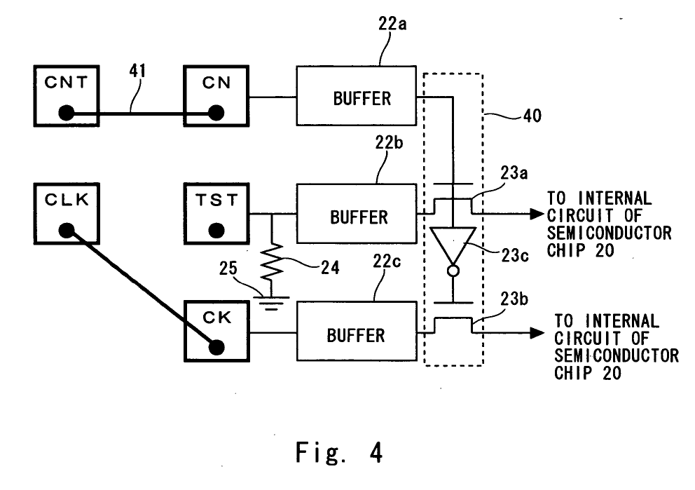

FIG. 3 is a top view showing the structure of the semiconductor device according to the first embodiment of the present invention, from which the quartz oscillator is removed. FIG. 4 shows how to connect the input terminal for the clock signal and the internal circuit in the semiconductor device according to the first embodiment of the present invention, from which the quartz oscillator is removed.

The structure of FIG. 3 differs from that of FIG. 1 in that the quartz oscillator 30 is provided outside the semiconductor device 1a, with the result that the wires 41 do not connect between the terminal VDD2 and the terminal VDD3, between the terminal CLK0 and the terminal CK, and between the terminal GND2 and the terminal GND3.

Further, the clock signal is output from the quartz oscillator 30 provided outside the semiconductor device 1a through the terminal CLK0 thereof to the lead CLK of the semiconductor device 1a. In addition, the power is applied to the terminal VDD3 of the quartz oscillator 30 independently of the semiconductor device 1a. The terminal GND3 of the quartz oscillator 30 is connected with a ground potential 33 independently of the semiconductor device 1a.

A description is next given of the operation of the semiconductor device according to the first embodiment of the present invention, from which the quartz oscillator is removed with reference to the drawings.

The structure of FIG. 2 differs from that of FIG. 4 in that the lead CLK is connected with the terminal TST in FIG. 2, while the lead CLK is connected with the terminal CK in FIG. 4. Further, the buffer 22a is set so as to turn on the switch 40 (for example, HIGH level) all the time in order to always select the clock signal input to the terminal CLK and the terminal CK, not the clock signal input to the terminal TST, for instance.

Being supplied with the power from the terminal VDD3, the quartz oscillator 30 outputs a predetermined clock signal from the terminal CLK0 to the lead CLK of the semiconductor device 1.

The clock signal input from the quartz oscillator 30 to the lead CLK is output to the terminal CK of the semiconductor chip 20. Then, the semiconductor chip 20 is operated in response to the clock signals from the quartz oscillator 30. Here, no signal is input to the terminal TST, and the resistor 24 functions to pull the residual potential between the terminal TST and the buffer 22b down to the ground potential 25 to save the power consumption of the buffer 22b.

In this way, even if the quartz oscillator 30 is removed from the semiconductor device 1 according to the first embodiment of the present invention, the semiconductor device 1a can exert the same function. At this time, even if the same semiconductor chip 20 and quartz oscillator 30 are used, the lead CLK is connected with the terminal CK instead of the terminal TST of the semiconductor chip 20, making it possible to readily attain the semiconductor device 1a not incorporating the quartz oscillator 30. Therefore, it is arbitrarily selected whether the quartz oscillator 30 is incorporated in the semiconductor device or provided outside the semiconductor device.

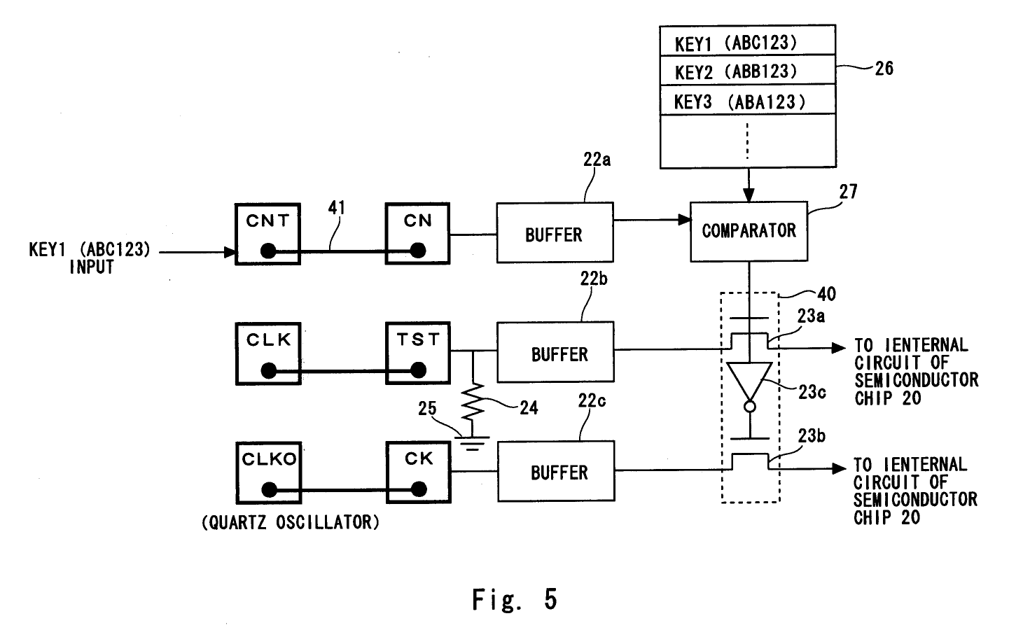

Next, another example of the semiconductor device according to the embodiment of the present invention is described. FIG. 5 shows how to connect the input terminal for the clock signal with the internal circuit in the semiconductor device as another example of the embodiment of the present invention.

The structure of FIG. 5 differs from that of FIG. 2 in that an identifier memory 26 and a comparator 27 are additionally provided. The identifier memory 26 stores plural keys composed of plural predetermined symbols and characters as identifiers (for example, key 1 (ABC123), key 2 (ABB231), key 3 (ABA321), . . . ). The plural keys are preset.

The comparator 27 compares the key input from the lead CNT through the terminal CN with the keys stored in the identifier memory 26, and outputs, when both the keys match with each other, a switching signal for switching the switch 40.

Hence, the clock signals can be supplied to the internal circuit of the semiconductor chip 20 through the lead CLK and the terminal TST from the outside.

The operation of the thus-structured semiconductor device as another example of the first embodiment of the present invention is discussed with reference to the drawings.

In switching the normal operation to the test operation, for example, the key 1 (ABC123) is input to the lead CNT. The key 1 input to the lead CNT is output through the terminal CN and the buffer 22a to the comparator 27.

Next, the comparator 27 compares the input key 1 with all the plural keys stored in the identifier memory 26, and outputs, when any of them are matched, the switching signal for switching the switch 40.

Subsequently, the switch 40 selects the clock signal input to the lead CLK and the terminal TST, not the clock signal input to the terminal CLK0 and the terminal CK. Further, the semiconductor device 1 is set so as to read the clock signal from the quartz oscillator 30.

Next, the clock signal from quartz oscillator 30, which can be read out, is read and input as the test clock signal to the lead CLK.

Then, the test clock signal input to the lead CLK is output to the internal circuit of the semiconductor chip 20 through the lead CLK and the terminal TST.

In this embodiment, a single key may be set in the identifier memory 26. Alternatively, even when the target key matches a flagged one out of the plural preset keys, the switch 40 may be switched over to allow the supply of the clock signal from the outside to the internal circuit of the semiconductor chip 20.

As mentioned above, in the semiconductor device as another example of the first embodiment of the present invention, the key is set as a predetermined identifier for operating the switch 40, thereby preventing the simultaneous input of the clock signal from the quartz oscillator 30 and the externally generated clock signal to the semiconductor chip 20. In addition thereto, the keys is kept in secret, so it is very difficult for other persons than a manufacturer and a user to externally supply the clock signal to read out a program recorded on a ROM etc. of the internal circuit of the semiconductor chip 20, which produces an effect of improving concealment.

In the above description, the keys are input using the lead CNT, but the same applies to the case of inputting the plural keys to the other leads. In this case, for example, when a combination of the plural keys matches the key stored in the identifier memory 26, the switching signal for switching the switch 40 is output to the buffer 22a.

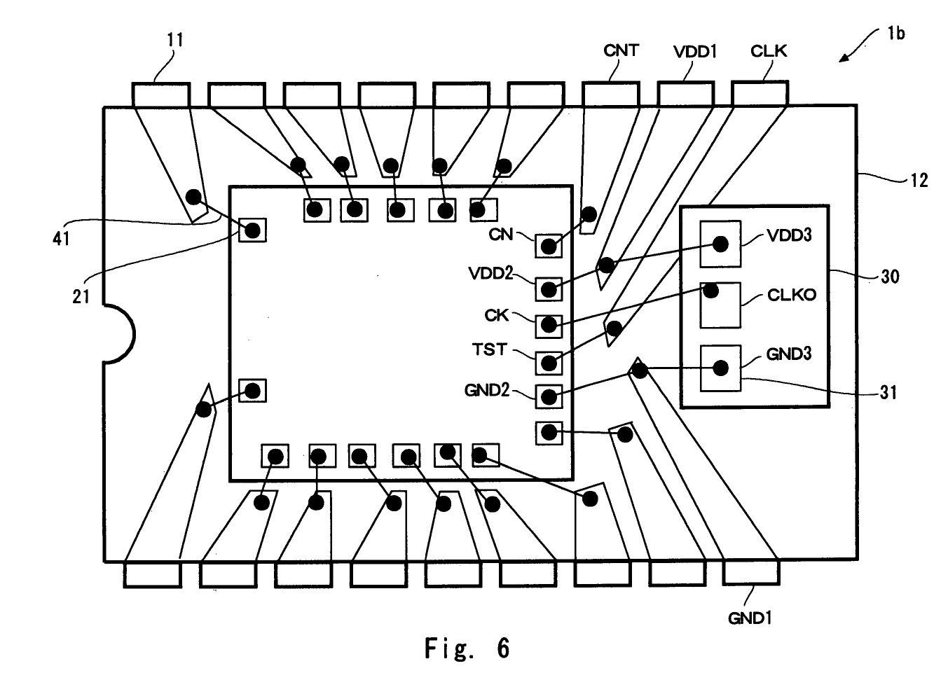

The structure of a semiconductor device according to another embodiment of the present invention is described with reference to the drawings. FIG. 6 is a perspective view showing the structure of the semiconductor device according to the second embodiment of the present invention.

The structure of FIG. 6 differs from that of FIG. 1 in that the quartz oscillator 30 is laminated on the semiconductor chip 20 in FIG. 1, while the quartz oscillator 30 is arranged in parallel with a semiconductor chip 30 in FIG. 6.

Even if a semiconductor device 1b is thus structured, the same beneficial effects as the first embodiment of the present invention can be attained.

It is apparent that the present invention is not limited to the above embodiment that may be modified and changed without departing from the scope and spirit of the invention.

What is claimed is:

1. A semiconductor device, comprising:
a piezoelectric oscillator; and
a semiconductor chip including a first clock signal input terminal receiving a clock signal output from the piezoelectric oscillator and a second clock signal input terminal receiving an externally generated clock signal.

2. The semiconductor device according to claim 1, wherein the semiconductor chip and the piezoelectric oscillator are laminated together.

3. The semiconductor device according to claim 1, wherein the semiconductor chip and the piezoelectric oscillator are arranged in parallel.

4. The semiconductor device according to claim 1, wherein the semiconductor chip further comprises a selector selecting one of the clock signal input to the first clock signal input terminal and the clock signal input to the second clock signal input terminal, and the semiconductor chip operates in accordance with the clock signal output from the piezoelectric oscillator when the selector selects the clock signal input to the first clock signal input terminal and operates in accordance with the externally generated clock signal when the selector selects the clock signal input to the second clock signal input terminal.

5. The semiconductor device according to claim 4, wherein when the externally generated clock signal is input to the second clock signal input terminal, the selector selects the clock signal input to the second clock signal input terminal.

6. The semiconductor device according to claim 4, wherein the selector selects the clock signal input to the second clock signal input terminal in response to input of predetermined number of pulses of the externally generated clock signal to the second clock signal input terminal.

7. The semiconductor device according to claim 4, wherein a predetermined identifier for operating the selector is set, and the selector operates only when an input identifier matches the predetermined identifier.

8. The semiconductor device according to claim 2, wherein the semiconductor chip further comprises a selector selecting one of the clock signal input to the first clock signal input terminal and the clock signal input to the second clock signal input terminal, and the semiconductor chip operates in accordance with the clock signal output from the piezoelectric oscillator when the selector selects the clock signal input to the first clock signal input terminal and operates in accordance with the externally generated clock signal when the selector selects the clock signal input to the second clock signal input terminal.

9. The semiconductor device according to claim 8, wherein when the externally generated clock signal is input to the second clock signal input terminal, the selector selects the clock signal input to the second clock signal input terminal.

10. The semiconductor device according to claim 8, wherein the selector selects the clock signal input to the second clock signal input terminal in response to input of predetermined number of pulses of the externally generated clock signal to the second clock signal input terminal.

11. The semiconductor device according to claim 8, wherein a predetermined identifier for operating the selector is set, and the selector operates only when an input identifier matches the predetermined identifier.

12. A semiconductor chip, comprising:
a first clock signal input terminal receiving a clock signal from a piezoelectric oscillator provided inside a semiconductor device where the semiconductor chip is provided; and
a second clock signal input terminal receiving an externally generated clock signal.

13. The semiconductor chip according to claim 12, further comprising a selector selecting one of the clock signal input to the first clock signal input terminal and the clock signal input to the second clock signal input terminal, wherein
the semiconductor chip operates in accordance with the clock signal output from the piezoelectric oscillator when the selector selects the clock signal input to the first clock signal input terminal and operates in accordance with the externally generated clock signal when the selector selects the clock signal input to the second clock signal input terminal.

14. The semiconductor chip according to claim 12, wherein when the externally generated clock signal is input to the second clock signal input terminal, the selector selects the clock signal input to the second clock signal input terminal.

15. The semiconductor chip according to claim 12, wherein the selector selects the second clock signal input terminal in response to input of predetermined number of pulses of the externally generated clock signal to the second clock signal input terminal.

16. The semiconductor chip according to claim 12, wherein a predetermined identifier for operating the selector is set, and the selector operates only when an input identifier matches the predetermined identifier.
